(19) United States
(12) Patent Application Publication
(10) Pub. No.: US 2003/0111724 A1
(43) Pub. Date: Jun. 19, 2003

(54) Inspection device for inspecting the position of trademark on integrated circuit

(76) Inventors: Chen-Ping Su, Taipei (TW); Ming-Lang Tsai, Taipei (TW); Yung-Yuan Lee, Taipei (TW)

Correspondence Address: Chen-Ping Su, PO Box 82-144, TAIPEI, TW

(21) Appl. No.: 10/156,129

(22) Filed: May 29, 2002

(30) Foreign Application Priority Data
Dec. 19, 2001 (TW) 090222629

(51) Int. Cl. H01L 23/34

(52) U.S. Cl. 257/723

(57) ABSTRACT

An inspection device for the position of trademark on integrated circuit board is disclosed. The inspection device comprises an inspection plate made from a transparent acrylic material having a plurality of inspection engraving lines thereon and a plurality of position holes; and a base seat having mounted with a plurality of position pegs which correspond to the position holes on the inspection plate; thereby a pin platform for inspection is positioned between the base seat and the inspection plate and the inspection line is corresponding to the trademark on the surface of the integrated circuit (IC) to proceed with the inspection.

### BACKGROUND OF THE INVENTION

(a) Technical Field of the Invention

The present invention relates to an inspection device for inspecting the position of trademark on integrated circuit, and in particular, a simple device, which allows convenient, rapid and precise inspection of the position of trademark on the surface of an integrated circuit.

(b) Description of the Prior Art

Referring to FIGS. 1 and 2, there is shown an integrated circuit on a pin platform being packed. In order to provide identification of good quality of the product, the surface of the integrated circuit (IC) 10 is printed with a specific trademark (for instance, patterns, symbols, marks, characters, words, model numbers, etc), so as to maintain the reputation of the product and increase the value of the product. The position of trademark printed onto the surface of he IC has to be precise and consistent. To inspect the position of the trademark, manufacturers make use of a projector to enlarge the trademark and is then projected for inspection, comparing whether the position of the trademark is precise and consistent.

However, each inspection and comparison employing the specific projector require laborious setting and adjustment of the specific projector prior to inspection procedures. Besides, the procedures for the inspection of trademark position require subsequent inspection of each IC 10. Thus, the method of inspection of trademark position on IC 10 is time-consuming and the cost of production with be increased.

### SUMMARY OF THE INVENTION

Accordingly, it is an object of the present invention to provide an inspection device for inspecting the position of trademark on integrated circuit, wherein the drawbacks of the conventional device can be mitigated by employing the present inspection device which provides a convenient, rapid and precise inspection of trademark position on the surface of the IC.

One aspect of the present invention is to provide an inspection device for inspecting the position of trademark on integrated circuit comprising an inspection plate made from a transparent acrylic material having a plurality of inspection engraving lines thereon and a plurality of position holes; and a base seat having mounted with a plurality of position pegs which correspond to the position holes on the inspection plate; thereby a pin platform for inspection is positioned between the base seat and the inspection plate and the inspection line is corresponding to the trademark on the surface of the integrated circuit (IC) to proceed with the inspection.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view of a pin platform and the integrated circuit (IC).

FIG. 2 is a front view of the IC.

FIG. 3 is a perspective exploded view of the present invention.

FIG. 4A is a sectional view illustrating the structure of the present invention.

FIG. 4B is a sectional view of a portion of the present invention.

FIG. 5 is a perspective view showing the application of the inspection device in accordance with the present invention.

FIG. 6 is a schematic view of the inspection device for the position of trademark on IC in accordance with the present invention.

FIG. 7 is a schematic view of an inspection plate of another preferred embodiment in accordance with the present invention.

FIG. 8 is a schematic view of the inspection device in accordance with the present invention.

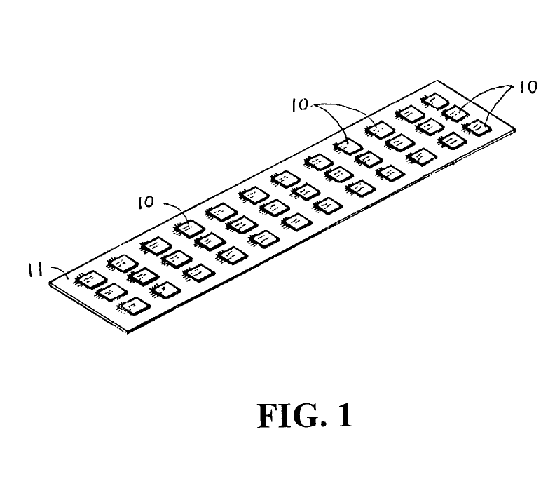

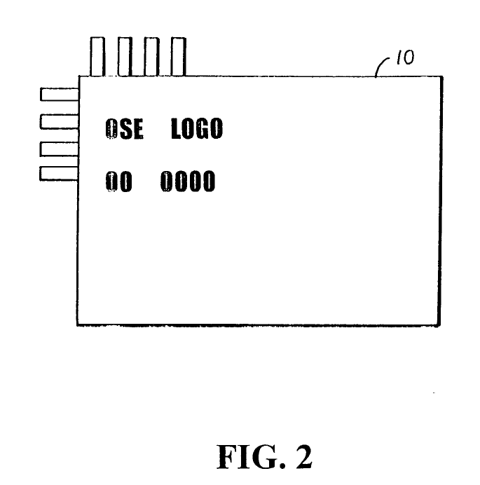

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

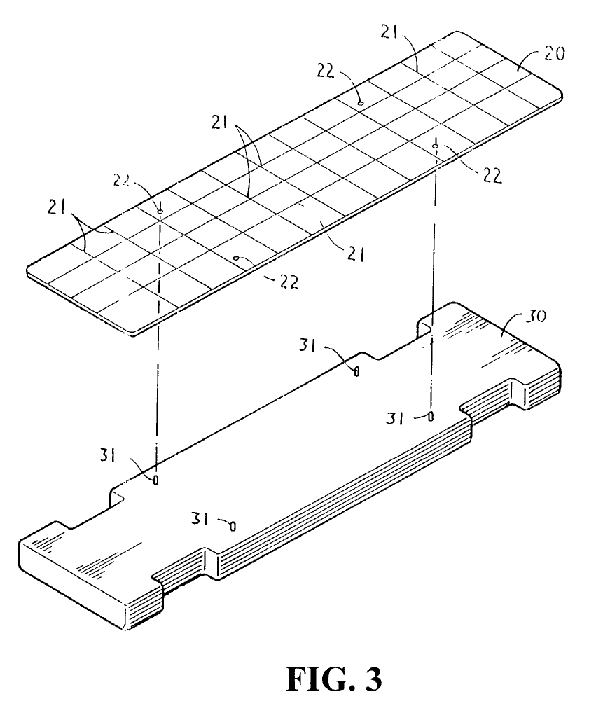

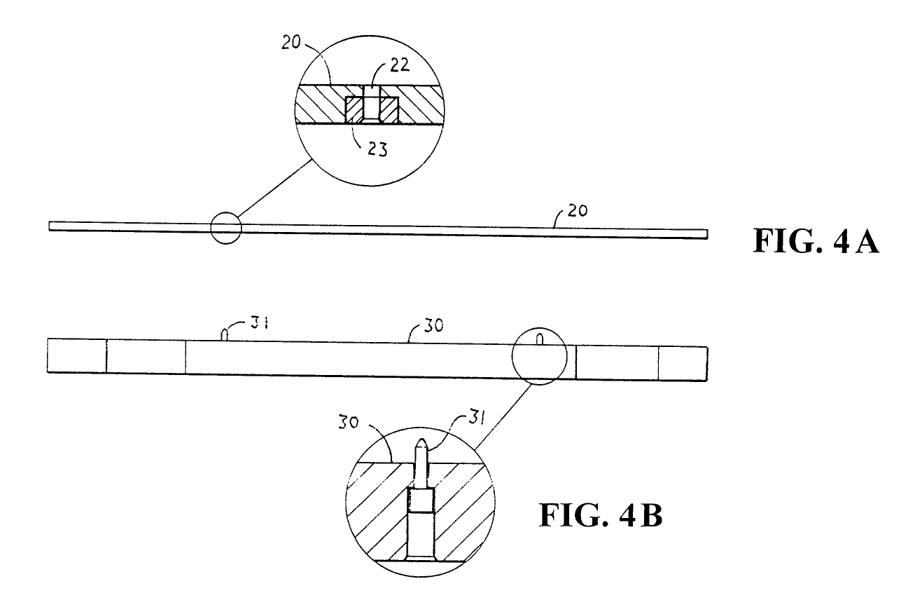

Referring to FIG. 3, there is shown an inspection device for trademark position on integrated circuit (IC) comprising an inspection plate 20 and a base seat 30, wherein the inspection plate 20 (also referring to FIG. 4) is made from a transparent acrylic material, and a plurality of inspection engraving lines 21 are provided on the plate 20. The lines 21 are arranged in vertical and in horizontal direction. A plurality of position holes 22 are provided on the inspection plate 20 at appropriate positions, and the bottom of the individual position hole 22 is provided with metallic sleeve 23 to ensure the precision of positioning.

The base seat 30 (also referring to FIGS. 4A and 4B) has a size depending on that of the inspection plate 20. A plurality of position pegs 31 are provided on the base seat 30, and the position pegs 31 correspond to the plurality of position holes 22 on the inspection plate 20. Due to the metallic sleeve 23 located at the bottom section of the position hole 22, the individual position peg 31 at the bottom edge can be easily inserted into the position hole 22.

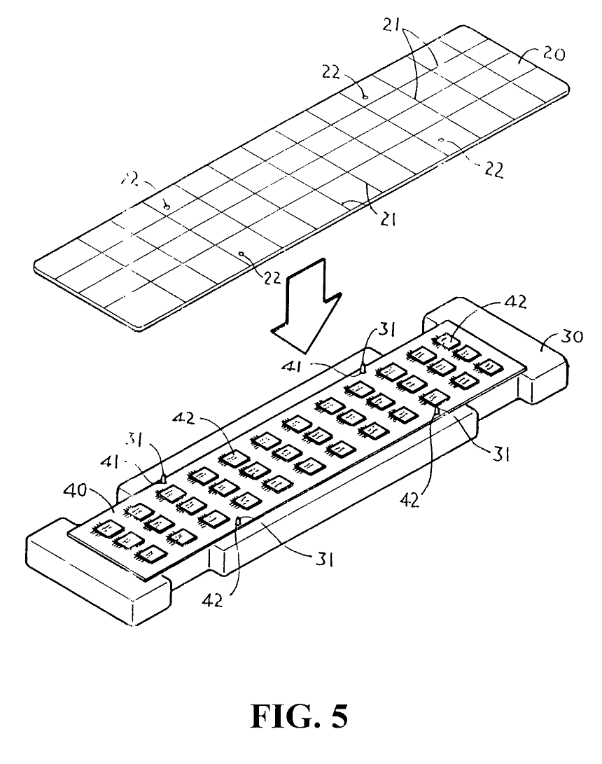

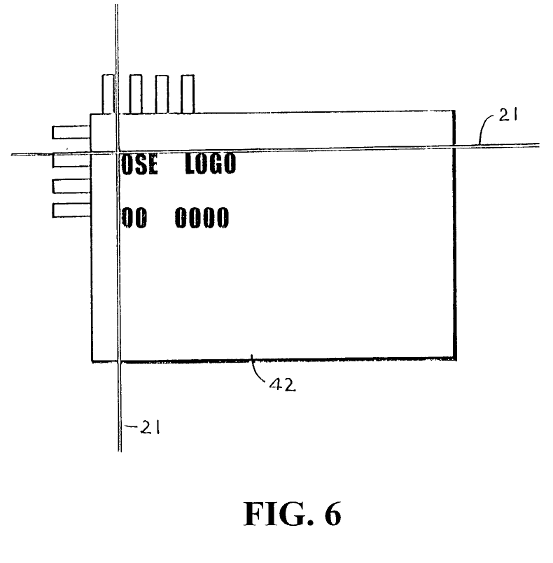

Referring to FIG. 5, the plurality of position pegs 31 on the base seat 30 are corresponding to the holes 41 on the pin platform 40, so that the pin platform 40 and the integrated circuit thereon 42 (with trademark being printed) are mounted onto the base at 30. The aperture 41 passes through the position peg 31 such that the pin platform 40 is positioned on the base seat 30 and is at a predetermined position. After that the plurality of position holes 22 on the inspection plate 20 pass through the position peg 31 such that the inspection plate 20 is similarly located on the base seat 30 and is at a predetermined position. The pin platform 40 is located between the inspection plate 20 and the base seat 30. Thus, due to the fact that the inspection plate 20 is a transparent plate and is provided with the inspection engraving lines 21, by means of the inspection engraving lines 21 to correspond to the trademark on the IC surface, the related position of the trademark with the engraving line 21 can be determined whether it is at a slanting position or biased to one direction (as shown in FIG. 6). At the same time, the IC 42 on the same pin platform 40 is undergone an inspection procedure. As a result, the present inspection device can inspect the trademark position on the IC surface rapidly and conveniently.

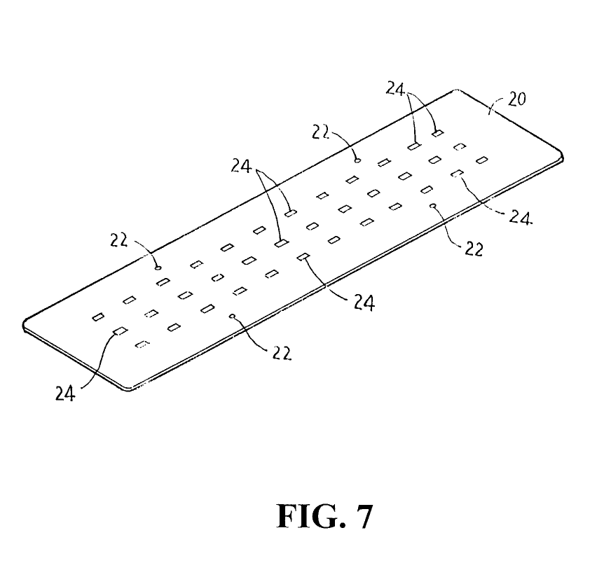

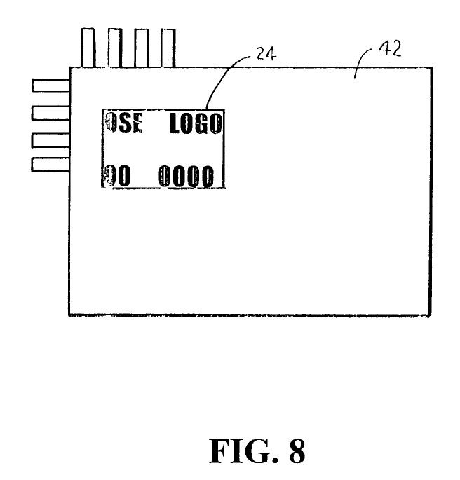

Further, the arrangement of the inspection engraving lines 21 on the inspection plate 20, other than in the vertical and the horizontal position, can be located at position shown in FIGS. 7 and 8, which is arranged on a plurality of inspection frames 24. The similar procedures can be employed to proceed with inspection of the trademark position. The arrangement of the inspection engraving lines 42 is dependent on the configuration of trademark on the IC 42 surface. The arrangement of the engraving lines 21 is lines corresponding to the position of trademark on the IC surface.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. An inspection device for inspecting trademark position on integrated circuit comprising
(a) an inspection plate made from a transparent acrylic material having a plurality of inspection engraving lines thereon and a plurality of position holes; and
(b) a base seat having mounted with a plurality of position pegs which correspond to the position holes on the inspection plate;
whereby a pin platform for inspection is positioned between the base seat and the inspection plate and the inspection line is corresponding to the trademark on the surface of the integrated circuit (IC) to proceed with the inspection.

2. The inspection device of claim 1, wherein the position of the inspection engraving lines are located based on he configuration of the trademark on the IC surface so that the lines are corresponding to the position of the trademark on the IC.

3. The inspection device of claim 1, wherein the bottom section of the position hole of the inspection plate is provided with metallic sleeves such that the individual pegs on the base seat are precisely inserted into the position hole.
